(19) United States
(12) Patent Application Publication
(10) Pub. No.: US 2025/0169105 A1
(43) Pub. Date: May 22, 2025

(54) MASK INTEGRATION FOR TRENCHED SEMICONDUCTOR DEVICE STRUCTURES

(71) Applicant: Wolfspeed, Inc., Durham, NC (US)

(72) Inventors: Woongsun Kim, Cary, NC (US); Naeem Islam, Morrisville, NC (US); Madankumar Sampath, Morrisville, NC (US); Sei-Hyung Ryu, Cary, NC (US)

(21) Appl. No.: 18/514,038

(22) Filed: Nov. 20, 2023

(51) Int. Cl. H01L 29/78; H01L 29/06; H01L 29/08; H01L 29/40; H01L 29/66

(52) U.S. Cl. CPC H10D 30/668; H10D 30/0297; H10D 62/105; H10D 62/154; H10D 64/117

(57) ABSTRACT

A semiconductor device includes a semiconductor layer structure comprising a junction field-effect transistor (JFET) region of a first conductivity type, a well region of a second conductivity type on the JFET region, a source region of the first conductivity type on the well region and a plurality of support shields of the second conductivity type. The support shields are spaced apart from one another in a first direction parallel to an upper surface of the semiconductor layer structure and extend through the source region, the well region and the JFET region. The semiconductor device further includes a trenched gate structure formed in the semiconductor layer structure between a pair of adjacent support shields. Edges of at least two of the JFET region, the well region and the source region are aligned in a second direction perpendicular to the first direction.

### FIELD

The present disclosure relates generally to semiconductor devices, and, more particularly, to trenched semiconductor devices.

### BACKGROUND

A metal insulating semiconductor field-effect transistor (“MISFET”) is a well-known type of semiconductor transistor that may be used as a switching device. A MISFET is a three-terminal device that has gate, drain and source terminals and a semiconductor body. A source region and a drain region are formed in the semiconductor body that are separated by a channel region, and a gate electrode (which is often referred to as a gate finger) is separated from the channel region by a thin insulating layer often referred to as a “gate dielectric layer.” A MISFET may be turned on or off by applying an appropriate bias voltage to the gate finger. When a MISFET is turned on (i.e., is in its “on-state”), current is conducted through the channel region of the MISFET between the source region and drain regions. When the bias voltage is removed from the gate finger (or reduced below a threshold level of the MISFET device, which may be a negative voltage in some cases), the current ceases to conduct through the channel region.

There is an increasing demand for high power semiconductor switching devices that can pass large currents in their on-state and block large voltages (e.g., hundreds or thousands of volts) in their reverse blocking state. In order to support high current densities and block such high voltages, power MOSFETs and insulated gate bipolar transistors (IGBTs) typically have a vertical structure with the source and drain on opposite sides (e.g., on top and bottom) of a thick semiconductor layer structure in order to block higher voltage levels. In very high power applications, the semiconductor switching devices are typically formed in wide band-gap semiconductor material systems (herein the term “wide band-gap semiconductor” encompasses any semiconductor having a band-gap of at least 1.4 electron volts) such as, for example, silicon carbide (SiC).

Vertical power semiconductor devices that include a MOSFET transistor can have a planar gate design in which the gate fingers are formed on top of the semiconductor layer structure or, alternatively, may have the gate fingers buried in respective trenches within the semiconductor layer structure. MOSFETs having buried gate fingers are typically referred to as gate trench MOSFETs or, more generally, trenched semiconductor devices. With the planar gate design, the channel region of each unit cell transistor is horizontally disposed underneath a gate finger. In contrast, in the gate trench MOSFET design, the channel is vertically disposed. Gate trench MOSFETs may provide enhanced performance, but typically require a more complicated manufacturing process.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

### SUMMARY

The present invention, as manifested in one or more embodiments, is directed to semiconductor devices and fabrication methods thereof.

In accordance with an embodiment of the present inventive concept, a semiconductor device is provided which may include a semiconductor layer structure comprising a junction field-effect transistor (JFET) region of a first conductivity type, a well region of a second conductivity type on the JFET region, a source region of the first conductivity type on the well region and a plurality of support shields of the second conductivity type. The support shields are spaced apart from one another in a first direction parallel to an upper surface of the semiconductor layer structure and extend through the source region, the well region and the JFET region. The semiconductor device further includes a trenched gate structure formed in the semiconductor layer structure between a pair of adjacent support shields. Edges of at least two of the JFET region, the well region and the source region are aligned in a second direction perpendicular to the first direction.

In accordance with another embodiment of the present inventive concept, a semiconductor device is provided which may include a semiconductor layer structure comprising a JFET region of a first conductivity type, a well region of a second conductivity type on the JFET region, and a source region of the first conductivity type on the well region. The semiconductor device further includes a trenched gate structure formed in the semiconductor layer structure between a pair of adjacent support shields, the trenched gate structure including a gate electrode. The JFET region does not extend completely underneath the trenched gate structure.

In accordance with an embodiment of the present inventive concept, a method of fabricating a semiconductor device includes: forming a semiconductor layer structure comprising a JFET region of a first conductivity type, a well region of a second conductivity type on at least a portion of the JFET region, a source region of the first conductivity type on at least a portion of the well region, and a plurality of support shields of the second conductivity type, the support shields being spaced apart from one another in a first direction parallel to an upper surface of the semiconductor layer structure and extending, in a second direction perpendicular to the first direction, through the source region, the well region and the JFET region; and forming a trenched gate structure in the semiconductor layer structure between a pair of adjacent support shields. At least two of the JFET region, the well region and the source region are formed using a same ion implantation mask.

In accordance with another embodiment of the present inventive concept, a method of fabricating a semiconductor device includes: forming a JFET region of a first conductivity type; forming a well region of a second conductivity type on at least a portion of the JFET region; forming a source region of the first conductivity type on at least a portion of the well region; and forming a trenched gate structure including a gate electrode, the trenched gate structure extending, in a first direction perpendicular to an upper surface of the semiconductor device, through the source region, the well region, and into at least a portion of the JFET region. At least two of the JFET region, the well region and the source region are formed using a same ion implantation mask.

In accordance with an embodiment of the present inventive concept, a method of fabricating a semiconductor device includes: sequentially forming a JFET region of a first conductivity type, a well region of a second conductivity type, and a source region of the first conductivity type, the JFET region, the well region and the source region being stacked in a first direction perpendicular to an upper surface of the semiconductor device; and forming a trenched gate structure, the trenched gate structure including a gate electrode and extending in the first direction through the source region, the well region, and into at least a portion of the JFET region. At least two of the JFET region, the well region and the source region are formed using a same ion implantation mask.

Aspects of the present inventive concept can provide substantial beneficial technical effects. By way of example only and without limitation, techniques according to embodiments of the present disclosure may provide one or more of the following advantages, among other benefits:
reduces fabrication cost and complexity in manufacturing a vertical semiconductor device by employing an integrated ion implantation mask for forming two or more active device implant layers or regions;
easily integrates with existing fabrication processes without requiring additional masks or increasing device fabrication complexity.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1A is a top plan view depicting at least a portion of an illustrative power MOSFET device;

FIG. 1B is a top plan view depicting at least a portion of the power MOSFET device of FIG. 1A with various top-side metal and dielectric layers thereof omitted to show underlying gate fingers and gate buses;

FIG. 2A is an enlarged view of a portion A of the top plan view of the illustrative power MOSFET device shown in FIG. 1B;

FIGS. 2B-2D are cross-sectional views depicting portions of the illustrative power MOSFET device of FIG. 2A taken along lines B-B′, C-C′ and D-D′, respectively;

FIGS. 3A-3G are plan and perspective cross-sectional views depicting intermediate process steps in an example method of fabricating a conventional power MOSFET device;

FIG. 4 is a cross-sectional view depicting an enlarged portion of the semiconductor device shown in FIG. 3G after a gate insulating layer and gate are formed in the gate trench;

FIGS. 5A-5E are perspective cross-sectional views depicting intermediate process steps in an example method of fabricating a vertical power semiconductor device (e.g., MOSFET), as well as other power devices utilizing a trenched structure (e.g., IGBT), according to one or more embodiments of the present disclosure;

FIG. 6 is a cross-sectional view depicting an enlarged portion of the illustrative vertical semiconductor device shown in FIG. 5E, according to one or more embodiments of the present disclosure after a gate insulating layer and gate are formed in the gate trench;

FIGS. 7A-7D are perspective cross-sectional views depicting intermediate process steps in an example method of fabricating a vertical semiconductor power device (e.g., MOSFET), as well as other power devices utilizing a trenched structure (e.g., IGBT), according to one or more embodiments of the present disclosure;

FIG. 8 is a cross-sectional view depicting an enlarged portion of the illustrative vertical semiconductor device shown in FIG. 7D, according to one or more embodiments of the present disclosure after a gate insulating layer and gate are formed in the gate trench;

FIGS. 9A-9D are cross-sectional views of gate trench power semiconductor devices according to embodiments of the present invention that use different combinations of channeled and non-channeled ion implantation processes to form the support shields and JFET layer; and

FIGS. 10A-10G are cross-sectional views of gate trench power semiconductor devices according to embodiments of the present invention that have different ones of the JFET layer, the well layer and the source layer aligned with a sidewall of a support shield.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present invention, as manifested in one or more embodiments thereof, may be described herein in the context of vertical semiconductor power devices (e.g., metal-oxide-semiconductor field-effect transistor (MOSFET) and insulated-gate bipolar transistor (IGBT) devices), as well as other power devices utilizing a trenched structure, and methods of fabricating such devices. It is to be appreciated, however, that the invention is not limited to the specific devices and/or methods illustratively shown and described herein. Rather, it will become apparent to those skilled in the art given the teachings herein that numerous modifications to the embodiments shown are contemplated and are within the scope of the present inventive concept. That is, no limitations with respect to the embodiments shown and described herein are intended or should be inferred.

It will be understood that, although ordinal terms such as “first,” “second,” etc., may be used herein to describe various elements, these elements should not be limited by such terms. These terms are used merely to distinguish one element from another. For example, a first element could be termed a second element and similarly, a second element could be termed a first element, without departing from the scope of the present disclosure. As used herein, the term “and/or” includes any and all combinations of one or more of the associated listed items.

For the purpose of describing and claiming embodiments of the present disclosure, the term MISFET as may be used herein is intended to be construed broadly and to encompass any type of metal-insulator-semiconductor field-effect transistor. The term MISFET is, for example, intended to encompass semiconductor field-effect transistors that utilize an oxide material as their gate dielectric (e.g., MOSFETs), as well as those that do not. In addition, despite a reference to the term “metal” in the acronyms MISFET and MOSFET, the terms MISFET and MOSFET are also intended to encompass semiconductor field-effect transistors wherein the gate is formed from a non-metal material such as, for instance, polysilicon; the terms “MISFET” and “MOSFET” may be used interchangeably herein.

Although the overall fabrication method and structures formed thereby as described herein are considered to be entirely novel, certain individual processing steps required to implement a portion or portions of the method(s) according to one or more embodiments of the inventive concept may utilize conventional semiconductor fabrication techniques and/or conventional semiconductor fabrication tooling. These techniques and tooling will already be familiar to one having ordinary skill in the relevant art and are therefore not described in detail herein. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are incorporated by reference herein in their entireties. It is emphasized that while some individual processing steps are set forth herein, those steps are merely illustrative and one skilled in the art may be familiar with several equally suitable alternatives that would also fall within the scope of the present disclosure.

It will be understood that when an element such as a layer, region, or structure is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or structure is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below,” “above,” “upper,” “lower,” “top,” “bottom,” “under,” “over,” “horizontal,” “vertical,” etc., as may be used herein, are intended to describe a spatial relationship of one element, layer, or region to another element, layer, or region as illustrated in the figures, rather than an absolute position of the element, layer, or region. It will be understood that these terms and those discussed above are intended to encompass different orientations of the device in addition to the orientation depicted in the figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are contemplated. For example, a region illustrated or described as square or rectangular may have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common reference numbers and may not be subsequently re-described.

Silicon carbide based power semiconductor devices that have gate trenches, such as vertical power MOSFETs and IGBTs, are attractive for many applications due, at least in part, to their inherent lower specific on-resistance, which may result in more efficient operation for power switching applications. Trench-gate vertical power devices exhibit lower specific resistance during on-state operation primarily because the channel is formed in the sidewall of the gate trench. Moreover, carrier mobility in the sidewall channels of trench-gate power devices may be about two to four times higher than the corresponding carrier mobility in the horizontal channel of a standard (i.e., non-trenched gate) power device. This increased channel mobility results in increased current density during on-state operation allowing for higher switching speeds. Furthermore, the trench-gate design reduces the overall pitch of the device, allowing for denser integration. The lower conduction losses (due to the reduced on-state resistance) and improved switching speeds make trench-gate power devices well-suited for high frequency power applications having low to moderate voltage blocking requirements (e.g., 600-1200 volts). These devices may have reduced requirements for associated passive components, low cost, low weight and require relatively simple cooling schemes. As MOSFETs are currently the most widely used silicon carbide based trench-gate power semiconductor devices, the discussion below focuses primarily on MOSFET embodiments. It will be appreciated, however, that the described embodiment(s) may alternatively be implemented using non-oxide gate dielectric layers (e.g., nitrides, high dielectric constant materials, etc.), and that the same techniques may be used to form other trenched power semiconductor devices such as IGBTs, gate-controlled thyristors and the like.

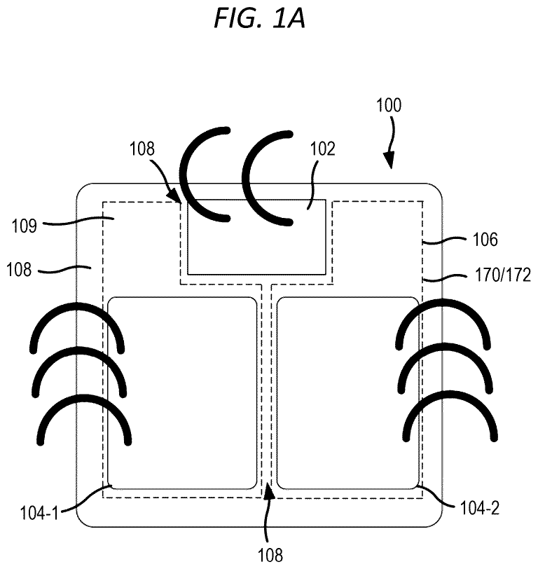

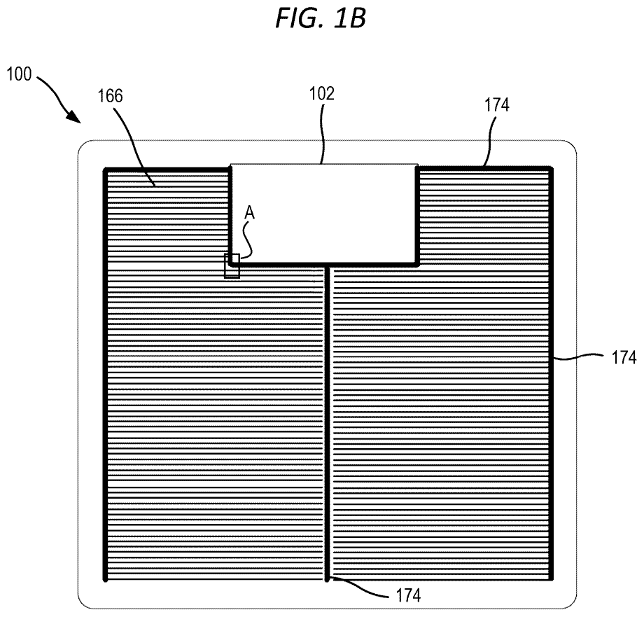

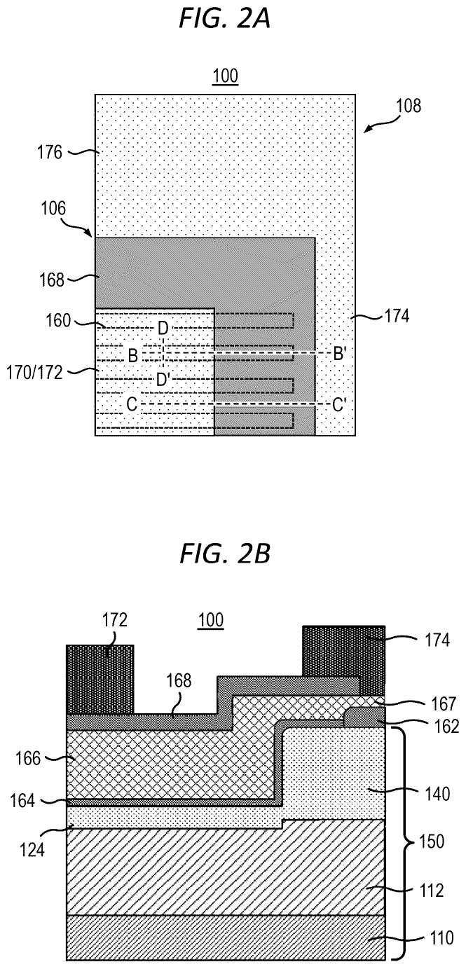

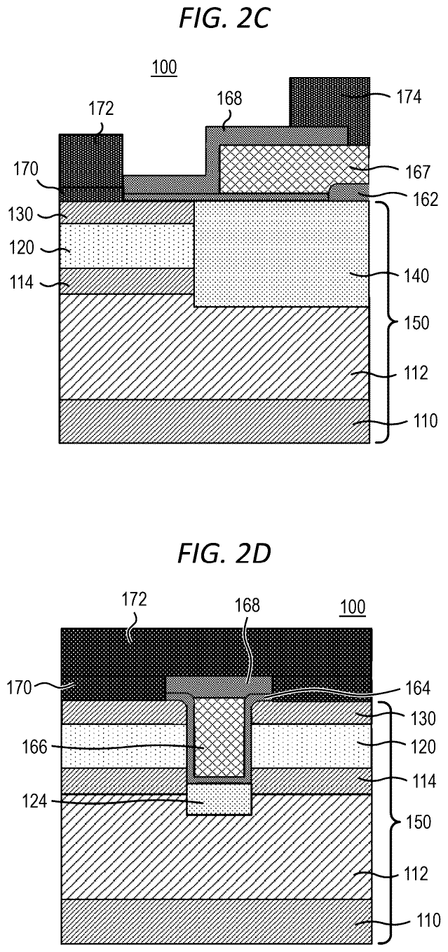

FIG. 1A is a top plan view depicting at least a portion of an illustrative power MOSFET device 100. FIG. 1B is a top plan view depicting at least a portion of the power MOSFET device 100 of FIG. 1A with various top-side metal and dielectric layers thereof omitted to show gate fingers and gate buses. FIG. 2A is an enlarged view of a portion A of the top view of FIG. 1B. FIGS. 2B-2D are cross-sectional views taken along lines B-B, C-C and D-D, respectively, of FIG. 2A. It will be appreciated that the thicknesses of the various layers, patterns and elements in FIGS. 2A-2D, as well as the other figures herein, are not necessarily drawn to scale.

Referring first to FIGS. 2C-2D, it can be seen that the power MOSFET device 100 includes a semiconductor layer structure 150 and a plurality of metal and dielectric layers that are formed on either side of the semiconductor layer structure 150.

Referring to FIG. 1A, a gate bond pad 102 and one or more source bond pads 104-1, 104-2 are formed on an upper side of the semiconductor layer structure 150 (FIGS. 2B-2D), and a drain pad (not shown to simplify the figures) may be provided on a bottom side of the MOSFET device 100. Each of the gate and source bond pads 102, 104 may be formed of a metal, such as aluminum, that bond wires can be readily attached to via conventional wire bonding techniques such as thermo-compression or soldering. A protective layer 109 such as a polyimide layer may cover the entire top surface of MOSFET device 100 except for the gate and source bond pads 102, 104.

The MOSFET device 100 includes a source contact 170/172 (indicated by the dashed boxes in FIG. 1A) that electrically connects source regions 130 (FIGS. 2C-2D) in the semiconductor layer structure 150 to the source bond pads 104-1, 104-2. The source bond pads 104-1, 104-2 may be portions of the source contact 170/172 that are exposed through openings in the protective layer 109 in some embodiments. The source contact 170/172 may generally overlie or correspond to an “active region” 106 of the MOSFET device 100 where unit cell transistors are located. An inactive region 108 of MOSFET device 100 surrounds (i.e., extends around) the active region 106. The inactive region 108 may include a termination region that extends around a periphery of the device that includes guard rings, junction termination elements or other termination structures, a gate pad region that underlies the gate bond pad 102, and gate bus regions (discussed below).

Bond wires are shown in FIG. 1A that may be used to connect the gate bond pad 102 and the source bond pads 104-1, 104-2 to external circuits or the like. The drain pad (not explicitly shown) on the bottom side of MOSFET device 100 may be connected to an external circuit through, for example, an underlying sub-mount (not explicitly shown).

Referring to FIG. 1B, the MOSFET device 100 may further include a plurality of gate fingers 166 that are connected to the gate pad 102 via one or more gate buses 174. The gate fingers 166 may comprise, for example, a doped polysilicon pattern. The gate fingers 166 may, for example, extend horizontally across the semiconductor layer structure 150 (as shown in FIG. 1B) or vertically across the semiconductor layer structure 150. Other configurations may be used (e.g., the unit cells may have a hexagonal configuration). The gate fingers 166 are formed at least partly within gate trenches in the upper surface of the semiconductor layer structure 150. The gate pad 102 and the gate buses 174 may comprise metal structures in example embodiments and are in the inactive region 108 of MOSFET device 100.

FIG. 2A is a greatly enlarged view of a portion “A” of FIG. 1B which illustrates a portion of the MOSFET device 100 where several of the gate fingers 166 (FIG. 1B) of the MOSFET device 100 connect to one of the gate buses 174. As shown in FIG. 2A, the gate bus 174 is connected to (and optionally integral with) a gate pad 176 (which may be the gate bond pad 102 shown in FIG. 1A or a separate structure that is electrically connected to the gate bond pad 102). The connection between the gate bus 174 and the gate pad 176 may be a direct connection as shown in FIG. 2A, or alternatively may be through a gate resistor (not explicitly shown) or other conductive element. A plurality of gate trenches 160 are formed in the semiconductor layer structure 150 and end near the gate bus 174. The source contact 170/172 extends over the gate trenches 160 in the active region 106. An intermetal dielectric layer 168 (e.g., a silicon oxide layer) insulates the gate fingers 166 (FIG. 1B), the gate bus 174 and the gate pad 176 from the source contact 170/172.

FIGS. 2B-2D illustrate the layer structure of the illustrative MOSFET device 100. The MOSFET device 100 includes a substrate 110. The substrate 110 may comprise, for example, a single crystalline 4H silicon carbide (4H-SiC) semiconductor substrate that is heavily-doped with n-type impurities (i.e., an n+ silicon carbide substrate). An n-type silicon carbide drift region 112 may be formed on an upper surface of the substrate 110. The n-type silicon carbide drift region 112 may, for example, be formed by epitaxial growth on the silicon carbide substrate 110. The n-type silicon carbide drift region 112 may be a lightly-doped n-type (n-) region, and may be referred to herein as either a drift “region” or a drift “layer.” In example embodiments, the n-type silicon carbide drift region 112 may have a doping concentration of, for example, about 1×10¹⁴ to 5×10¹⁶ dopants/cm³. The n-type silicon carbide drift region 112 may be a thick region, having a vertical height above the substrate 110 of, for example, about 3-100 microns (μm). An upper portion of the n-type silicon carbide drift region 112 may be more heavily doped (e.g., a doping concentration of 1×10¹⁶ to 1×10¹⁷ dopants/cm³) than a lower portion thereof to provide a JFET region 114 in the upper portion of the n-type silicon carbide drift region 112.

Moderately-doped p-type (p) silicon carbide well regions 120 (“p-wells”) may be formed on an upper surface of the current spreading layer 114. The p-wells 120 may be formed by, for example, ion implantation. Heavily-doped n-type (n+) silicon carbide source regions 130 are then formed in upper portions of the semiconductor layer structure 150 by, for example, ion implantation. As shown in FIGS. 2B and 2D, deep shielding regions 124 may be provided underneath the respective gate trenches 160. The deep shielding regions 124 may extend through the JFET region 114 and into the drift region 112. While not visible in the figures (since deep shielding connection patterns are outside the views shown in the cross-sections of FIGS. 2B-2D), heavily-doped p-type (p+) silicon carbide deep shielding connection patterns are formed that electrically connect the deep trench shielding regions 124 to the source contact 170/172. Heavily-doped p-type (p+) regions 140 are provided in upper portions of the semiconductor layer structure 150 and may be formed by ion implantation. The heavily-doped p-type (p+) regions 140 are formed in both the active and inactive regions 106, 108 of MOSFET device 100. The substrate 110, the drift region 112, the JFET region 114, the p-wells 120, the deep shielding regions 124, the deep shielding connection patterns, the source regions 130 and the heavily-doped p-type (p+) regions 140 form the semiconductor layer structure 150. Each of these regions/layers may comprise silicon carbide. Thus, the semiconductor layer structure 150 may be a wide bandgap semiconductor layer structure 150.

As discussed above, a plurality of gate trenches 160 are formed in an upper surface of the semiconductor layer structure 150 (e.g., by etching). It will be appreciated that only a small portion of each gate trench 160 is visible in FIG. 2A. A gate dielectric layer 164 lines a bottom surface, sidewalls and end walls of each gate trench 160. Respective gate fingers 166 may substantially fill each gate trench 160, and are separated from the semiconductor layer structure 150 by the gate dielectric layer 164. The term “fill” (or “filling,” or like terms) as may be used herein is intended to refer broadly to either completely filling a defined space (e.g., gate trench 160) or partially filling the defined space; that is, the defined space need not be entirely filled but may, for example, be partially filled or have voids or other spaces throughout. At the end of the gate trench 160, each gate finger 166 may include a gate finger extension 167 that protrudes out of the gate trench 160 and extends laterally (i.e., horizontally) across the semiconductor layer structure 150. The gate dielectric layer 164 and a field oxide layer 162 separate each gate finger extension 167 from the semiconductor layer structure 150. At least a portion of the gate bus 174 is formed on the gate finger extension 167 to provide electrical connection between the gate finger 166 and the gate bus 174.

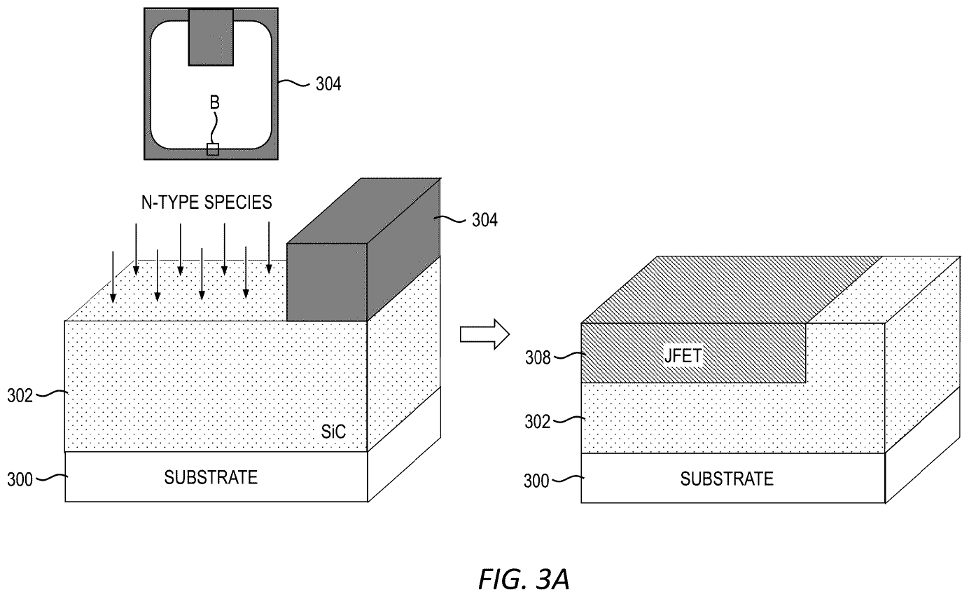

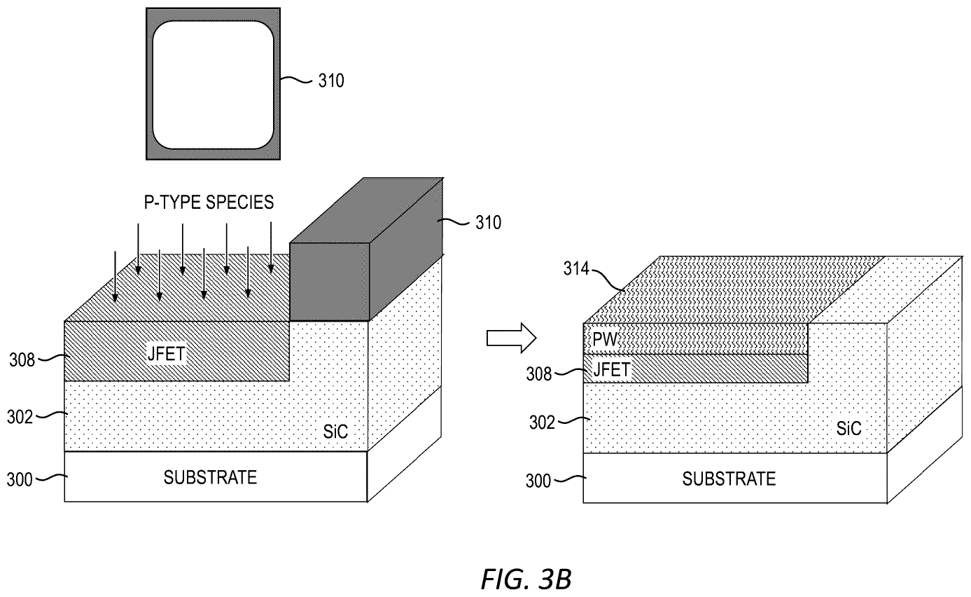

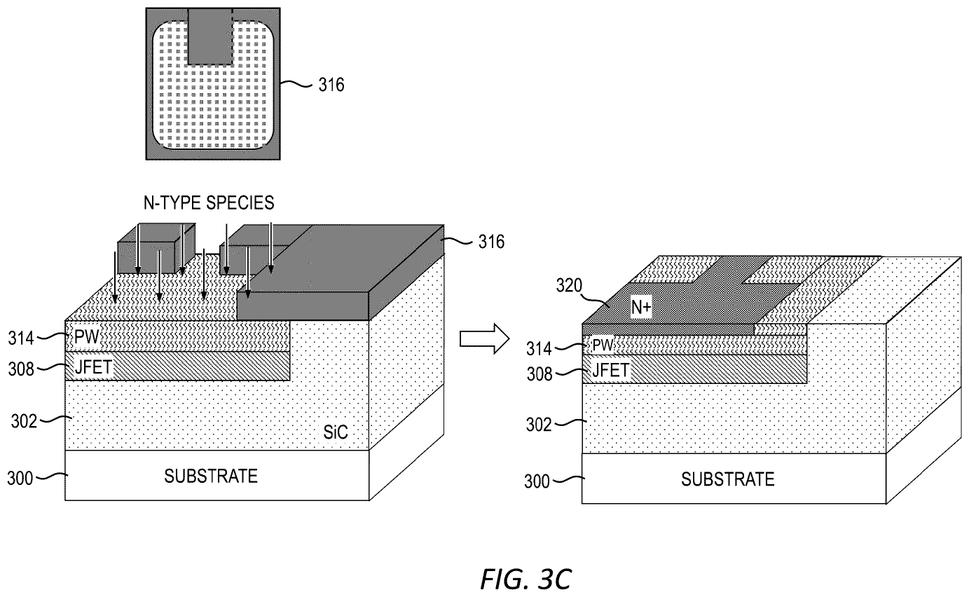

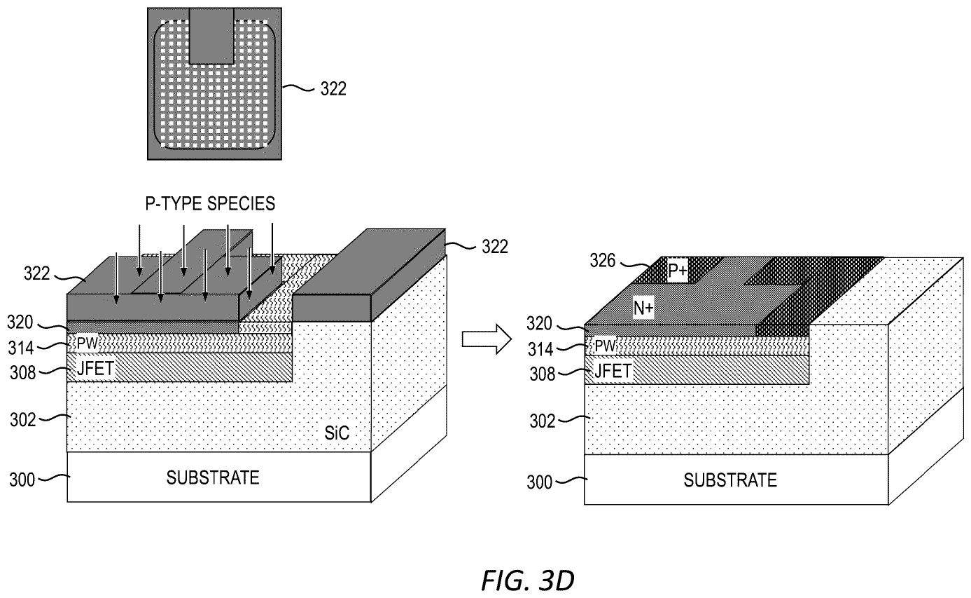

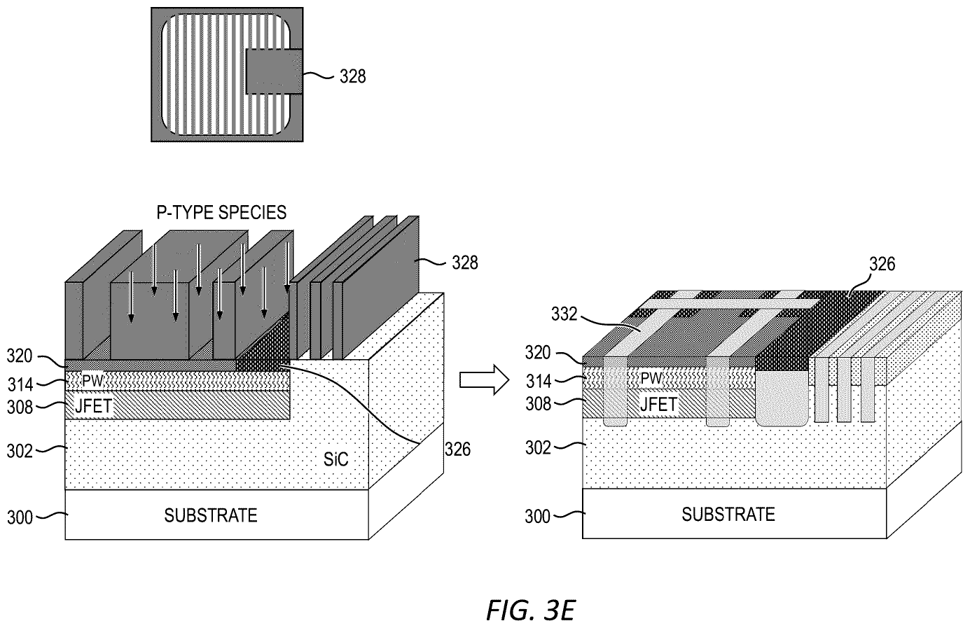

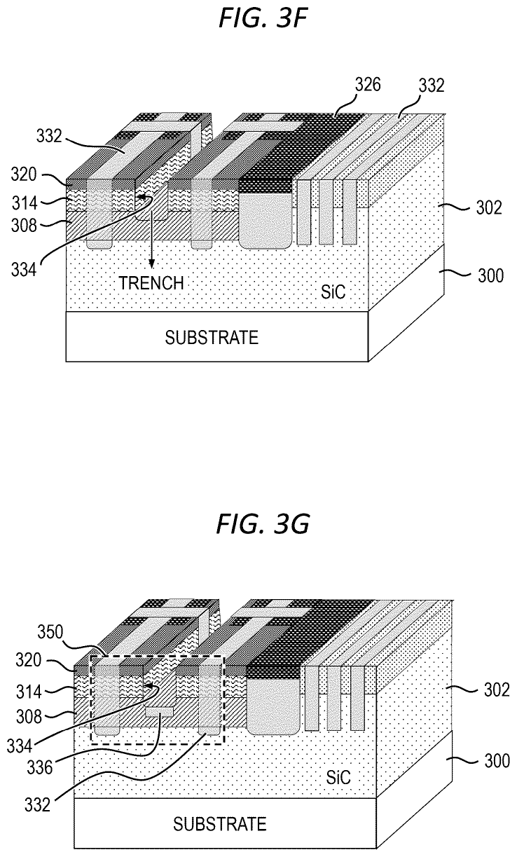

FIGS. 3A-3G are plan and perspective cross-sectional views depicting intermediate process steps in an example method of fabricating a conventional power MOSFET device. In FIGS. 3A-3E, the figure at the upper left is a plan view showing the power MOSFET device and an ion implantation mask that is formed thereon, and the lower view(s) are perspective cross-sectional views of the portion of the power MOSFET device and ion implantation mask in the region labelled “B.”

With reference to FIG. 3A, a junction field-effect transistor (JFET) implant step is shown that is used to form a preliminary JFET region 308 of the power MOSFET device. During this process step, a semiconductor substrate 300 having a drift region 302 formed thereon is provided. The semiconductor substrate 300 and the drift region 302 may each comprise, for example, silicon carbide (SiC). A mask layer is formed on the upper surface of the drift region 302 and is then patterned using standard photolithography to form a first ion implantation mask 304 on a defined region(s) of an upper surface of the substrate 302. The plan view in the upper left corner of FIG. 3A shows the regions where the first ion implantation mask 304 is formed. In some embodiments, the first ion implantation mask 304 may comprise an oxide or nitride material (e.g., silicon oxide, silicon nitride, etc.) of a prescribed thickness (e.g., about 3 microns (μm), or about 1 μm in the case of a channeling implant).

Using the first ion implantation mask 304, a species of a first conductivity type (e.g., N-type species, such as nitrogen or phosphorous) is implanted into the portion of the drift region 302 exposed through the first ion implantation mask 304 (i.e., the portion of the drift region 302 that is not covered by the first ion implantation mask 304). The N-type species may be relatively deeply implanted into the drift region 302 using, for example, a random or channeling ion implantation process. A depth of the N-type species into the drift region 302 may be controlled as a function of ion implant energy, as will be known by those skilled in the art. The first ion implantation mask 304 may then be removed, such as by etching. In this manner, a JFET layer or region 308 is formed in the upper portion of the drift region 302.

FIG. 3B depicts the formation of a P-well layer in the drift region 302. Specifically, a second ion implantation mask 310 is formed on a defined region of the upper surface of the semiconductor structure, leaving the JFET layer 308 and a region that is underneath a later formed gate bond pad 102 exposed. Like the first ion implantation mask 304 shown in FIG. 3A, the second ion implantation mask 310 may comprise an oxide or nitride material (e.g., silicon oxide, silicon nitride, etc.) of a prescribed thickness (e.g., about 2 μm).

Using the second ion implantation mask 310, a species of a second conductivity type (e.g., P-type species, such as aluminum) is implanted into the portion of the drift region 302 exposed by the second ion implantation mask 310 (i.e., a region not covered by the second ion implantation mask 310) to form a p-well layer or region 314 in the upper surface of the JFET layer 308. The P-type species may be implanted using, for example, a random or channeling ion implantation process. An implant depth of the P-type species into the JFET layer 308 may be controlled (e.g., as a function of ion implant energy) such that the P-type species is not driven entirely through the JFET layer 308, thereby leaving a portion of the N-type JFET layer 308 remaining. The second ion implantation mask 310 may then be removed, such as by etching, resulting in a structure including a P-well layer 314 formed in the upper surface of the JFET layer 308 on the drift region 302.

In FIG. 3C, an N-plus implant process is performed. With reference to FIG. 3C, a third ion implantation mask 316 is formed on the upper surface of the semiconductor structure, leaving selected portions of the P-well layer 314 exposed. Like the first ion implantation mask 304 shown in FIG. 3A, the third ion implantation mask 316 may comprise an oxide or nitride material (e.g., silicon oxide, silicon nitride, etc.) of a prescribed thickness. Because the N-plus implant is more shallow compared to the deep implant used to form the JFET layer 308, less implant energy is required during the ion implantation, and hence the third ion implantation mask 316 used for the N-plus implant process may be thinner (e.g., about 1 μm) than the first ion implantation mask 304 (FIG. 3A) used to form the JFET layer 308.

Using the third ion implantation mask 316, a species of the first conductivity type (e.g., N-type species) is implanted into a region exposed by the third ion implantation mask 316 (i.e., a region not covered by the third ion implantation mask 316). The N-type species may be implanted using, for example, a random or channeling ion implantation process. A depth of the N-type species into the P-well layer 314 may be controlled such that the N-type species is not driven entirely through the P-well layer 314, thereby leaving a portion of the underlying P-well layer 314 remaining. The third ion implantation mask 316 may then be removed, such as by etching, resulting in a structure including an N+ layer or region 320 formed in the upper surface of a portion of the P-well layer 314, which in turn is formed in the upper surface of the JFET layer 308.

FIG. 3D depicts a P-plus implant process. A fourth ion implantation mask 322 is formed on the semiconductor structure to expose portions of the P-well layer 314 in which the N+ layer 320 is not present; that is, the fourth ion implantation mask 322 may be patterned to cover the N+ layer 320 and a portion of the drift region 302 in which the JFET layer 308 is not formed. Like the third ion implantation mask 316 shown in FIG. 3C, the fourth ion implantation mask 322 may comprise an oxide or nitride material (e.g., silicon oxide, silicon nitride, etc.) of a prescribed thickness (e.g., about 1 μm).

Using the fourth ion implantation mask 322, a species of the second conductivity type (e.g., P-type species) is implanted into a region of the device exposed by the fourth ion implantation mask 322 (i.e., a region not covered by the fourth ion implantation mask 322). The P-type species may be implanted using, for example, a random or channeling ion implantation process. A depth of the P-type species into the P-well layer 314 may be controlled such that the P-type species is not driven entirely through the P-well layer 314, thereby leaving a portion of the underlying P-well layer 314 remaining. The fourth ion implantation mask 322 may then be removed, such as by etching, resulting in a structure including a P+ layer 326 formed in the upper surface of a portion of the P-well layer 314 and laterally adjacent to the N+ layer 320.

FIG. 3E depicts the formation of P-type support shields in the semiconductor structure. With reference to FIG. 3E, a fifth ion implantation mask 328 is patterned to expose portions of the semiconductor structure where the P-type shield regions are to be formed. The fifth ion implantation mask 328 may comprise an oxide or nitride material (e.g., silicon oxide, silicon nitride, etc.) of a prescribed thickness. Since the P-type support shields may be formed deeper in the semiconductor structure, thus requiring more implant energy, the fifth ion implantation mask 328 may be thicker (e.g., about 3 μm) compared to the thickness of the fourth ion implantation mask 322 used to form the P+ layer 326.

Using the fifth ion implantation mask 328, a species of the second conductivity type (e.g., P-type species) is implanted into prescribed regions of the semiconductor structure exposed by the fifth ion implantation mask 328. The P-type species may be implanted into the substrate using, for example, a random or channeling ion implantation process. A depth of the P-type species is controlled such that the P-type species is driven entirely through defined portions of the P+ layer 326, N+ layer 320 and JFET layer 308. The fifth ion implantation mask 328 may then be removed, such as by etching, resulting in a structure including P-type support shields 332 extending vertically through the defined regions of the P+ layer 326, N+ layer 320 and JFET layer 308, and into an upper portion of the underlying drift region 302.

FIG. 3F depicts a trench formation process in the semiconductor structure. Specifically, a trench 334 is formed extending vertically through a defined portion of the N+ layer 320 and the P-well layer 314, and at least partially into the JFET layer 308. The trench 334 can be formed, for example, using an etching process (e.g., anisotropic etching). An implant process (e.g., ion implantation or the like) is then used to form a deep shielding regions 336 proximate a bottom of the trench 334, as shown in FIG. 3G.

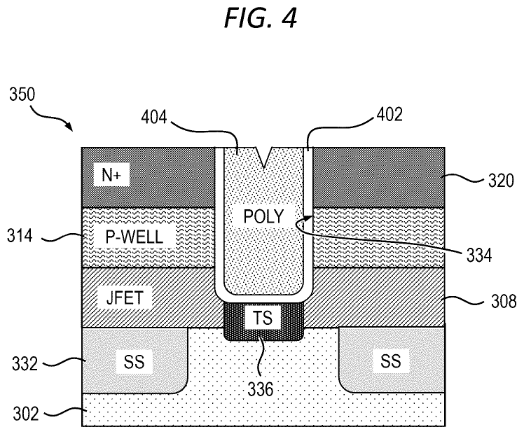

FIG. 4 is a cross-sectional view depicting an enlarged portion of the semiconductor device 350 shown in FIG. 3G. An insulating layer 402, such as an oxide (e.g., silicon dioxide), may be formed on sidewalls and a bottom of the trench 334 to conformally cover an interior surface of the trench 334. An oxide growth or deposition process may be used to form the insulating layer 402. The trench 334 is then filled with polysilicon to form a gate 404 of the semiconductor device 350. In FIG. 4, “SS” refers to the support shield and “DS” refers to the deep shielding region.

Conventionally, with reference to FIGS. 3A, 3B and 3C, separate masks 304, 310 and 316 are employed for each ion implantation process to form the JFET layer 308, P-well layer 314 and N+ layer 320, respectively. This approach can be costly and adds complexity to the fabrication process. Embodiments of the present disclosure beneficially exploit the fact that since a trench semiconductor device has a vertical channel along with a trenched sidewall, the N+ layer, P-well layer, and JFET layer can utilize the same mask for multiple implantation processes, which thereby reduces the overall cost of fabricating the semiconductor device.

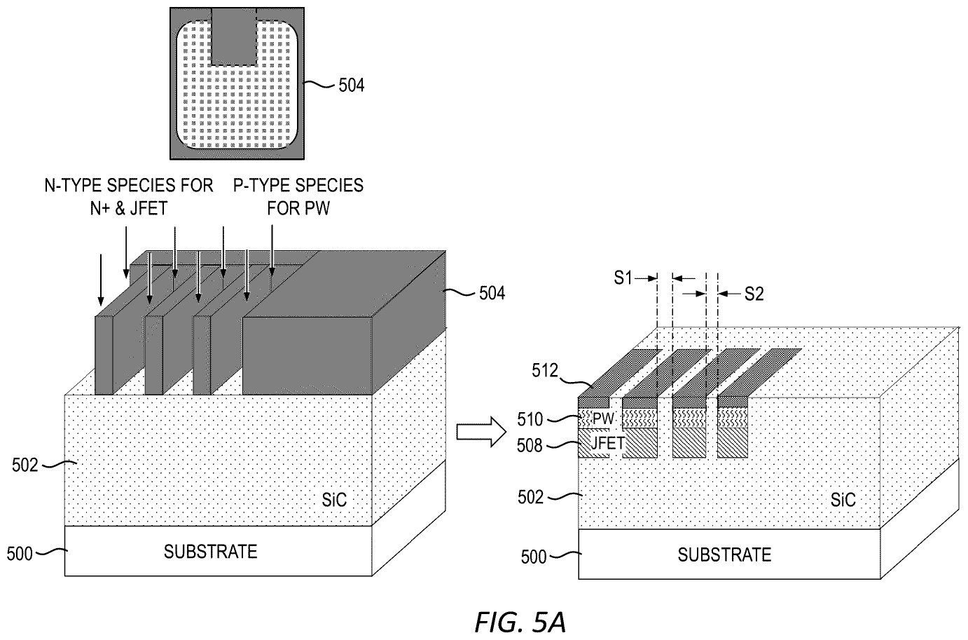

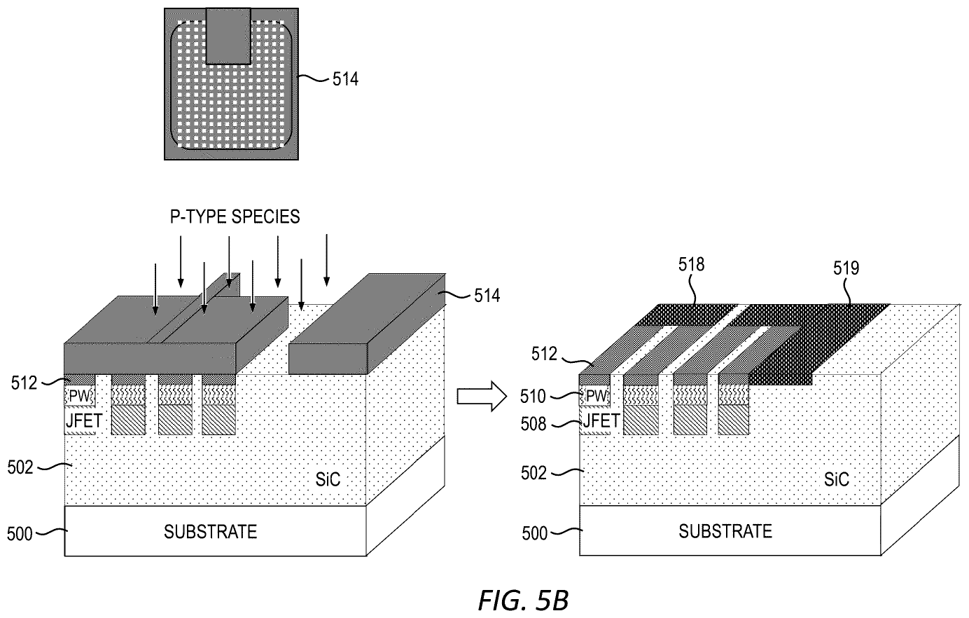

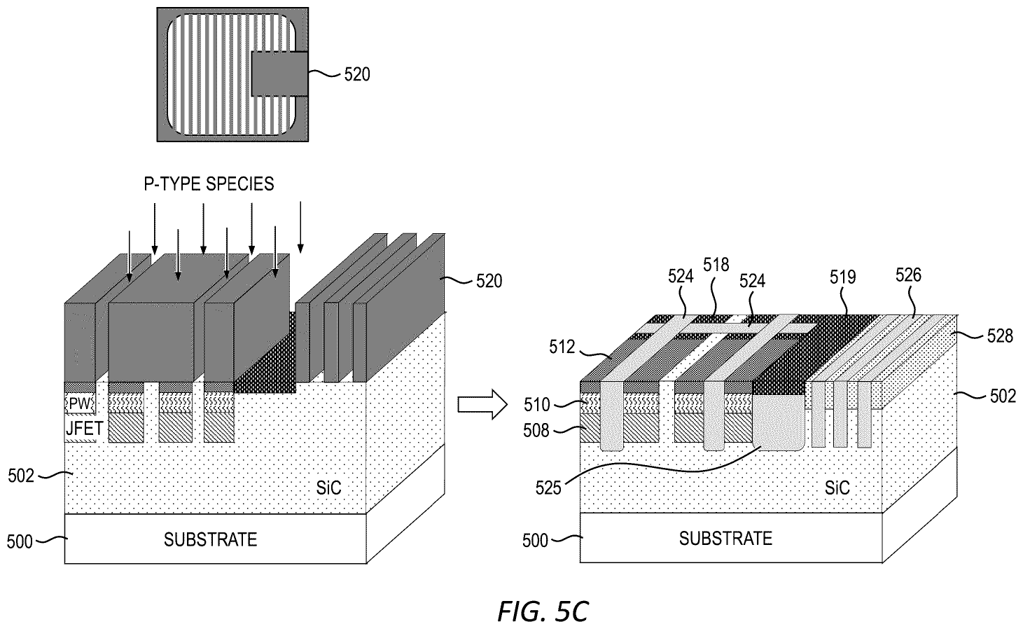

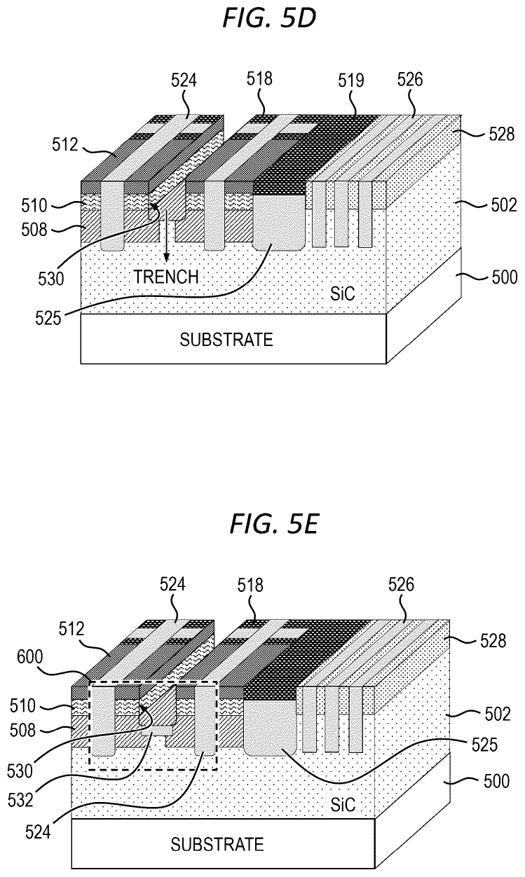

By way of illustration only and without limitation or loss of generality, FIGS. 5A-5E are plan and perspective cross-sectional views depicting intermediate process steps in an example method of fabricating a vertical semiconductor power device (e.g., MOSFET), as well as other power devices utilizing a trenched structure (e.g., IGBT), according to one or more embodiments of the present disclosure. The example method described in conjunction with FIGS. 5A-5E depicts the fabrication of a trench structure for a vertical power semiconductor device which utilizes an integrated oxide mask for N+, P-well and JFET implants. While the example fabrication process described in conjunction with FIGS. 5A-5E refer to specific layers as having either N-type or P-type conductivity, it is similarly contemplated that in some embodiments, the conductivity type of one or more active device layers may be reversed (e.g., a P-type layer replaced with an N-type layer), as will be appreciated by those skilled in the art.

With reference to FIG. 5A, a semiconductor substrate 500 is provided that has a drift region 502 formed on an upper surface thereof. The semiconductor substrate 500 and the drift region 502 may comprise, for example, silicon carbide (SiC), although embodiments are not limited thereto. A layer of photoresist material may be formed on an upper surface of the substrate. The photoresist material may be patterned using, for example, standard photolithographic and etching processes, to form a first ion implantation mask 504 on a defined region(s) of the upper surface of the drift region 502. In some embodiments, the first ion implantation mask 504 may comprise, for example, an oxide or nitride material (e.g., silicon oxide, silicon nitride, etc.) of a prescribed thickness (e.g., about 3 μm), although embodiments of the present invention are not limited to a specific material type or thickness of the first ion implantation mask 504. A thickness of the first ion implantation mask 504 may be configured based at least in part on a target depth of the implant species; for deeper implants, such as a JFET layer implant, a thicker mask may be used compared to a more shallow implant, such as an N+ layer implant. The plan view in the upper left portion of FIG. 5A shows the full first ion implantation mask 504.

Using the first ion implantation mask 504, a first implant process may be performed in which a species of a first conductivity type (e.g., N-type species, such as nitrogen, phosphorous, arsenic or antimony) is implanted into a prescribed region of the drift region 502 exposed by the first ion implantation mask 504 (i.e., a region of the drift region 502 not protected by the first ion implantation mask 504). During the first implant process, the N-type species may be deeply implanted into the substrate (e.g., to a depth of about 2 μm or greater, although embodiments are not limited to any specific depth or range of depths) using, for example, a random or channeling ion implantation process, although embodiments are not limited thereto. A depth of the N-type species into the drift region 502 may be controlled as a function of ion implant energy, as will be known by those skilled in the art. In this manner, a JFET layer 508 may be formed in the upper portion of the drift region 502.

Leaving the first ion implantation mask 504 in place, a second implant process may be performed in which a species of a second conductivity type (e.g., P-type species, such as aluminum, boron or indium) is implanted into the prescribed region of the semiconductor structure exposed by the first ion implantation mask 504 to form a P-well layer 510 on the JFET layer 508. A depth of the P-well layer 510 formed during the second implant process may be less than a depth of the JFET layer 508 formed during the first implant process, such that the N-type JFET layer 508 is disposed below the P-well layer 510 in a vertical direction (i.e., perpendicular to the upper surface of the substrate 500).

With the first ion implantation mask 504 still in place, a third implant process may be performed in which a species of the first conductivity type (e.g., N-type species, such as nitrogen, phosphorous, arsenic or antimony) is implanted into the prescribed region of the semiconductor structure that is exposed by the first ion implantation mask 504 to form a doped layer in the drift region 502, which may be an N-plus (N+) layer 512. A depth of the N+ layer 512 formed during the third implant process may be less than a depth of the JFET layer 508 formed during the first implant process and less than a depth of the P-well layer 510 formed during the second implant process, such that the JFET layer 508, P-well layer 510 and N+ layer 512 may be sequentially stacked and aligned with one another in the vertical direction.

It is to be appreciated that the order of the implant processes may be different from the order described above. For instance, in some embodiments, the implant process for forming the JFET layer 508 may be performed first, followed by the implant process for forming the N+ layer 512, followed by the implant process for forming the P-well layer 510. Alternative orders for forming the JFET layer 508, P-well layer 510 and N+ layer 512 are similarly contemplated. After forming the JFET layer 508, the P-well layer 510 and the N+ layer 512, the first ion implantation mask 504 may be removed, such as by etching or another means, as will be known by those skilled in the art.

As shown in FIG. 5A, in one or more embodiments, a lateral spacing, S1 and S2, between adjacent columns of active device layers—namely, the JFET layer 508, P-well layer 510 and N+ layer 512—in a horizontal direction parallel to the upper surface of the drift region 502, can be controlled by appropriately configuring the first ion implantation mask 504. The lateral spacing S1 may be a distance between adjacent columns of active device layers in a region where a gate trench is formed in a later processing step. The lateral spacing S2 may be a distance between adjacent columns of active device layers in a region where a support shield is formed in a later processing step. In some embodiments, the spacing (i.e., horizontal distance) S1 may be in a range of about 0 to 10 μm, and the spacing S2 may be in a range of about 0 to 10 μm. In some embodiments, the spacing S1 may be about 5-10 μm and the spacing S2 may be about 5-10 μm. In some embodiments, the spacing S1 may be about 0-2 μm and the spacing S2 may be about 0-2 μm. It is to be appreciated that embodiments of the present disclosure are not limited to any specific values for S1 and S2; furthermore, the spacing S1 need not be the same as the spacing S2 for a given active device layer. Using the same integrated mask pattern for all three implant processes, the spacing S1 will be the same for each of the JFET layer 508, P-well layer 510 and N+ layer 512. Using the same integrated mask pattern for all three implant processes, the spacing S2 will similarly be the same for each of the JFET layer 508, P-well layer 510 and N+ layer 512.

In some embodiments wherein it may be advantageous to individually control the spacing S1 and/or S2 for a given active device layer implant process relative to the other implant processes, the given implant process may be performed using a separate mask pattern. By way of example only and without limitation, Table 1 below depicts various combinations of forming each of the active device layers with spacing S1 and S2 for the N+ layer 512, P-well (PW) layer 510 and JFET layer 508.

TABLE 1

| | JFET | | PW | | N+ | |
|---|---|---|---|---|---|---|
| | S1 | S2 | S1 | S2 | S1 | S2 |
| 1 | 0 | 0 | 0 | 0 | 0 | 0 |
| 2 | | | | | >0 μm | 0 |
| 3 | | | | | 0 | >0 μm |
| 4 | | | | | >0 μm | >0 μm |
| 5 | | | >0 μm | 0 | 0 | 0 |
| 6 | | | | | >0 μm | 0 |
| 7 | | | | | 0 | >0 μm |
| 8 | | | | | >0 μm | >0 μm |
| 9 | | | 0 | >0 μm | 0 | 0 |
| 10 | | | | | >0 μm | 0 |
| 11 | | | | | 0 | >0 μm |
| 12 | | | | | >0 μm | >0 μm |
| 13 | | | >0 μm | >0 μm | 0 | 0 |
| 14 | | | | | >0 μm | 0 |
| 15 | | | | | 0 | >0 μm |
| 16 | | | | | >0 μm | >0 μm |
| 17 | >0 μm | 0 | 0 | 0 | 0 | 0 |
| 18 | | | | | >0 μm | 0 |
| 19 | | | | | 0 | >0 μm |
| 20 | | | | | >0 μm | >0 μm |
| 21 | | | >0 μm | 0 | 0 | 0 |
| 22 | | | | | >0 μm | 0 |
| 23 | | | | | 0 | >0 μm |
| 24 | | | | | >0 μm | >0 μm |
| 25 | | | 0 | >0 μm | 0 | 0 |
| 26 | | | | | >0 μm | 0 |
| 27 | | | | | 0 | >0 μm |
| 28 | | | | | >0 μm | >0 μm |
| 29 | | | >0 μm | >0 μm | 0 | 0 |
| 30 | | | | | >0 μm | 0 |
| 31 | | | | | 0 | >0 μm |
| 32 | | | | | >0 μm | >0 μm |
| 33 | 0 | >0 μm | 0 | 0 | 0 | 0 |
| 34 | | | | | >0 μm | 0 |
| 35 | | | | | 0 | >0 μm |
| 36 | | | | | >0 μm | >0 μm |
| 37 | | | >0 μm | 0 | 0 | 0 |
| 38 | | | | | >0 μm | 0 |
| 39 | | | | | 0 | >0 μm |
| 40 | | | | | >0 μm | >0 μm |
| 41 | | | 0 | >0 μm | 0 | 0 |
| 42 | | | | | >0 μm | 0 |
| 43 | | | | | 0 | >0 μm |
| 44 | | | | | >0 μm | >0 μm |
| 45 | | | >0 μm | >0 μm | 0 | 0 |
| 46 | | | | | >0 μm | 0 |
| 47 | | | | | 0 | >0 μm |
| 48 | | | | | >0 μm | >0 μm |
| 49 | >0 μm | >0 μm | 0 | 0 | 0 | 0 |
| 50 | | | | | >0 μm | 0 |
| 51 | | | | | 0 | >0 μm |
| 52 | | | | | >0 μm | >0 μm |
| 53 | | | >0 μm | 0 | 0 | 0 |
| 54 | | | | | >0 μm | 0 |
| 55 | | | | | 0 | >0 μm |
| 56 | | | | | >0 μm | >0 μm |
| 57 | | | 0 | >0 μm | 0 | 0 |
| 58 | | | | | >0 μm | 0 |
| 59 | | | | | 0 | >0 μm |
| 60 | | | | | >0 μm | >0 μm |
| 61 | | | >0 μm | >0 μm | 0 | 0 |
| 62 | | | | | >0 μm | 0 |
| 63 | | | | | 0 | >0 μm |
| 64 | | | | | >0 μm | >0 μm |

As shown in Table 1 above, of the 64 different combinations of making each feature with S1 and S1 spacing for the active device layers (N+ layer 512, P-well layer 510 and JFET layer 508), there will be four ways (Nos. 1, 22, 43 and 64 in Table 1) in which all three active device active layers may be fabricated using the same integrated implant mask; this will occur when the spacings S1 and S2 are the same for each of the JFET layer 508, P-well layer 510 and N+ layer 512. For the remaining 60 ways, at least a given one of the active device layers is fabricated using its own separate mask so that independent control over the S1 and/or S2 spacing may be achieved. For example, using approach Nos. 5, 9 or 13, no gap (i.e., S1=0, S2=0) is provided between laterally adjacent JFET and N+ device layers 508, 512, and therefore the same implant mask may be used to fabricate the JFET layer 508 and N+ layer 512. A separate implant mask may be used to form the P-well layer 512 for providing a non-zero S1 gap and no S2 gap (i.e., S1>0, S2=0) (no. 5 in Table 1), a non-zero S2 gap and no S1 gap (i.e., S1=0, S2>0) (no. 9 in Table 1), or non-zero S1 and S2 gaps (i.e., S1>0, S2>0) (No. 13 in Table 1) between laterally adjacent P-well layers 510, independently of the S1 or S2 spacing between laterally adjacent JFET layers 508 and N+ layers 512.

FIG. 5B depicts a P-plus (P+) implant process performed during fabrication of the semiconductor device. With reference to FIG. 5B, a second ion implantation mask 514 may be formed on the upper surface of the semiconductor structure. The second ion implantation mask 514 is configured to shield regions in which the JFET layer 508, P-well layer 510 and N+ layer 512 are formed. Like the first ion implantation mask 504 shown in FIG. 5A, the second ion implantation mask 514 may comprise, for example, an oxide or nitride material (e.g., silicon oxide, silicon nitride, etc.). Since the P+ implant may not require a deep implant process, a thickness of the second ion implantation mask 514 may be configured to be less than a thickness of the first ion implantation mask 504 used to form the JFET layer 508, P-well layer 510 and N+ layer 512. In one or more embodiments, the second ion implantation mask 514 may have a thickness of about 1 μm, although embodiments of the present disclosure are not limited thereto.

Using the second ion implantation mask 514, the species of the second conductivity type (e.g., P-type species, such as aluminum, boron or indium) may be implanted into a region of the semiconductor structure exposed by the second ion implantation mask 514 (i.e., a region of the drift region 502 exposed by the second ion implantation mask 514). The P-type species may be implanted into the drift region 502 using, for example, a random or channeling ion implantation process, although embodiments are not limited thereto. A depth of the P-type species into the drift region 502 may be controlled as a function of ion implant energy, as previously stated. The second ion implantation mask 514 may then be removed, such as by etching, resulting in a structure including a P-type layer 518 and a P-type pad area 519 formed in prescribed regions of the upper surface of the semiconductor structure exposed by the second ion implantation mask 514 and laterally adjacent to portions of the N+ layer 512. The pad area 519, which may be much wider than shown in some embodiments, may be used for gate buses and source buses in the vertical semiconductor device. In some embodiments, the P-type layer 518 and P-type pad area 519 may be formed at a similar depth in the drift region 502 to the N+ layer 512, although embodiments are not limited to any specific depth of the P-type layer 518 and P-type pad area 519.

With reference to FIG. 5C, support shields (e.g., P-type support shields) may be formed in the semiconductor structure. During the support shield formation process, a third ion implantation mask 520 may be patterned on the upper surface of the semiconductor structure that exposes portions of the semiconductor structure where the support shields are to be formed. The third ion implantation mask 520 may comprise, for example, an oxide or nitride material (e.g., silicon oxide, silicon nitride, etc.) of a prescribed thickness. Since the support shields may be formed deeper in the semiconductor structure, thus requiring more implant energy, the third ion implantation mask 520 may be thicker (e.g., about 3 μm) compared to the thickness of the second ion implantation mask 514 used to form the P-type layer 518.

Using the third ion implantation mask 520, the species of the second conductivity type (e.g., P-type species, such as aluminum, boron or indium) may be implanted into prescribed regions of the semiconductor structure exposed by the third ion implantation mask 520. The P-type species may be implanted using, for example, a random or channeling ion implantation process, although embodiments are not limited thereto. A depth of the implanted P-type species may be controlled such that the P-type species forms P-type support shields 524 that extend vertically (i.e., perpendicular to the upper surface of the semiconductor substrate 500) through prescribed portions of the N+ layer 512, P-well layer 510, and JFET layer 508 forming the active device layers, and at least partially into the underlying drift region 502. One or more P-type support shield stripes 524 may also be formed during this implant process which intersect the P-type support shields 524 formed through the active device layers 512, 510, 508. These P-type support shield stripes 524 may be used as connection structures for connecting to P-type deep shielding regions subsequently formed under subsequently formed gate trenches.

The implanted P-type species may also form a P-type shield region 525 below the P-type pad area 519 laterally adjacent to an edge of the active device layers, and one or more P-type guard rings 526 in an edge termination region of the semiconductor structure in which the active device layers (508, 510, 512) and the P-type pad area 519 are not present. It is to be appreciated that although three guard rings 526 are depicted in FIG. 5C, embodiments of the invention are not limited to any specific number of guard rings. For instance, in some embodiments, more than three guard rings 526 may be formed (e.g., 10 or more guard rings), while in other embodiments, less than three guard rings 526 may be formed (e.g., one or two guard rings). The third ion implantation mask 520 may then be removed, such as by etching, resulting in a structure including P-type support shields 524, p-type shield regions 525 and p-type guard rings 526 extending vertically through the prescribed regions of the P-type layer 518, N+ layer 512, P-well layer 510, P-type pad area 519, and/or edge termination region of the semiconductor structure, as shown in FIG. 5C. In some embodiments, a doped p-type (P-) layer 528 may be formed in the edge termination region of the semiconductor structure, proximate the upper portion of the drift region 502.

FIG. 5D depicts a trench formation process in the semiconductor structure. Specifically, in one or more embodiments, a trench 530 may be formed extending vertically into the active device layers—that is, through the N+ layer 512 and the P-well layer 510, and at least partially into the JFET layer 508—between an adjacent pair of P-type support shields 524. The trench 530 can be formed, for example, using an etching process (e.g., anisotropic etching). Thus, in one or more embodiments, the active device layers, including the N+ layer 512, P-well layer 510 and JFET layer 508, may extend laterally outwards from a sidewall of the trench 530 to an adjacent P-type support shield 524, and between the P-type support shield 524 and the adjacent P-type pad area 519 and/or the underlying P-type shield region 525.

An implant process (e.g., ion implantation or the like) may then be used to form a deep shielding region 532 proximate a bottom of the trench 530, for example by performing an ion implantation process or the like using a species of the second conductivity type (e.g., P-type, such as aluminum, boron or indium), as shown in FIG. 5E. The ion implantation mask used in this implant process is not shown in FIG. 5E so that the upper surface of the semiconductor layer structure is visible. In one or more embodiments, the deep shielding region 532 may be a shallow implant configured such that a bottom surface of the JFET layer 508 extends vertically below a bottom surface of the deep shielding region 532, although embodiments of the present invention are not limited thereto.

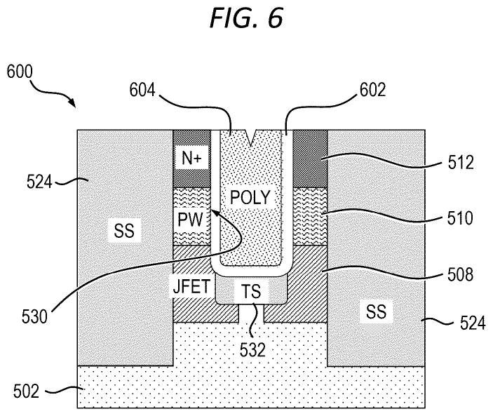

FIG. 6 is a cross-sectional view depicting an enlarged portion of the illustrative vertical semiconductor device 600 shown in FIG. 5E, according to one or more embodiments of the present disclosure. With reference to FIG. 6, an insulating layer 602, such as an oxide (e.g., silicon dioxide), may be formed on sidewalls and a bottom of the trench 530 to conformally cover inner wall and bottom surfaces of the trench 530. The term “cover” (or “covers” or “covering,” or like terms), as may be used herein, is intended to broadly refer to a material, layer or structure being on or over another material, layer or structure, but does not require the material, layer or structure to entirely cover the other material, layer or structure. The term “conformal” (or “conformally,” or like terms), as may be used herein in the context of a material layer or coating, is intended to refer broadly to a material layer or coating having a substantially uniform cross-sectional thickness relative to a contour of the surface to which the material layer is applied. An oxide growth or deposition process may be used to form the insulating layer 602.

The trench 530 may then be filled (e.g., using a deposition process) with polysilicon material (or another conductive material) to form a gate (i.e., gate electrode) 604 of the vertical semiconductor device 600, the gate 604 being disposed on the insulating layer 602 at least partly in the trench 530; that is, the insulating layer 602 and the gate 604 may be sequentially stacked on the inner wall and bottom surfaces of the trench 530. In this manner, the insulating layer 602 may serve as a gate oxide layer of the vertical semiconductor device 600.

Since the same integrated mask pattern is used for the JFET implant, P-well implant and N+ implant, the vertical semiconductor device 600 is configured such that an edge of each of the JFET layer 508, P-well layer 510 and N+ layer 512 is vertically aligned (i.e., coplanar) with an edge of the P-type support shield 524 facing the trench 530. Even for embodiments in which the spacing S1 and/or S2 is independently controlled for a given one of the active device layers relative to the other active device layers, at least two of the implant layers are configured having an edge that is vertically aligned with the edge of the P-type support shield 524 facing the trench 530.

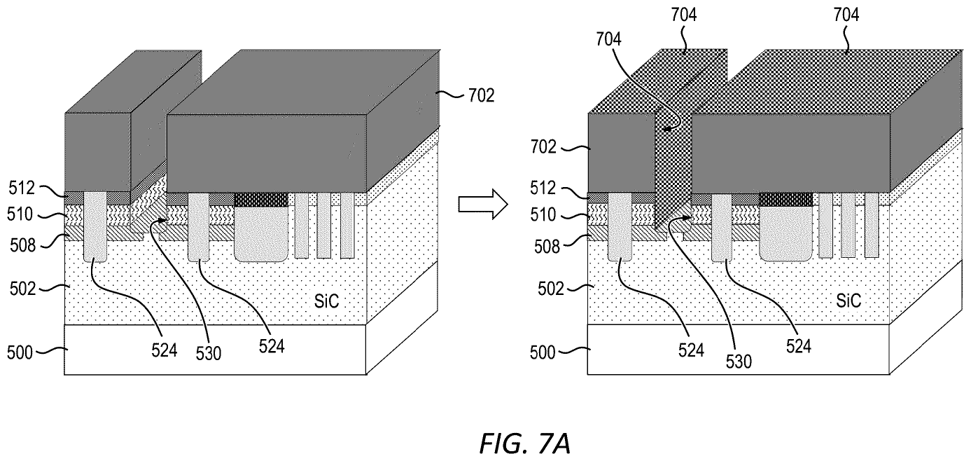

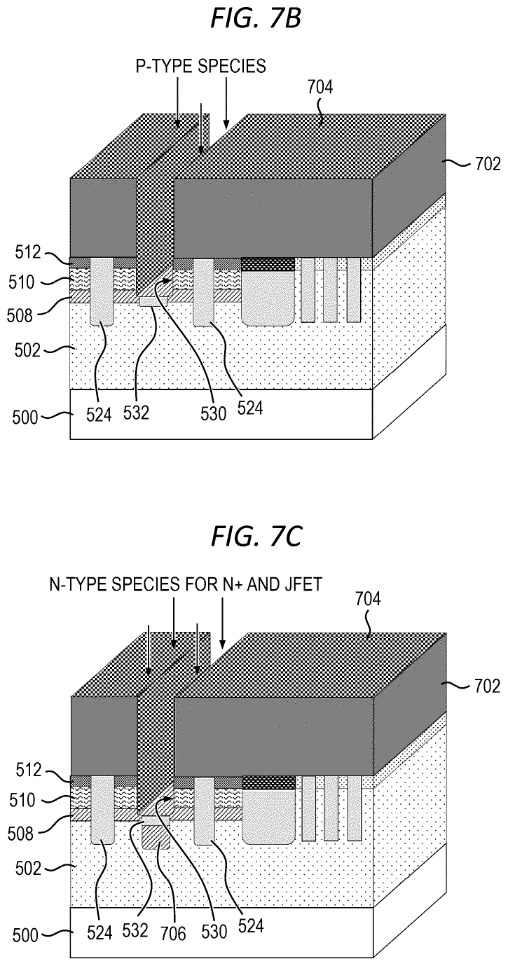

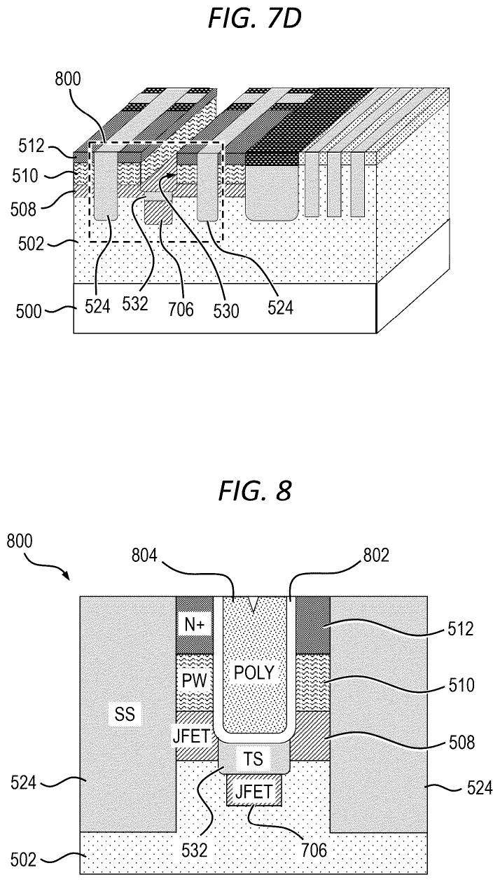

By way of illustration only and without limitation or loss of generality, FIGS. 7A-7D are perspective cross-sectional views depicting intermediate process steps in an example method of fabricating a vertical semiconductor power device (e.g., MOSFET), as well as other power devices utilizing a trenched structure (e.g., IGBT), according to one or more embodiments of the present disclosure. The semiconductor device fabricated using the method of FIGS. 7A-7D is essentially the same as the method used to form the semiconductor device shown in FIGS. 5A-5E, with an added JFET implant under the trench.

Specifically, FIG. 7A depicts the trench formation process in the illustrative vertical semiconductor structure. With reference to FIG. 7A, a fourth ion implantation mask 702 may be patterned on the upper surface of the semiconductor structure so as to define the location of the trench 530. The fourth ion implantation mask 702 may comprise, for example, an oxide or nitride material (e.g., silicon oxide, silicon nitride, etc.) of a prescribed thickness, such as, for example 2 μm. In one or more embodiments, the trench 530, which may be formed using an etching process (e.g., anisotropic etching or similar), extends vertically through the N+ layer 512 and P-well layer 510, and partially into the JFET layer 508, between a pair of adjacent P-shield regions 524. Thus, in one or more embodiments, the active device layers, including the N+ layer 512, P-well layer 510 and JFET layer 508, may extend laterally outwards from a sidewall of the trench 530 to an adjacent P-type support shield 524.

After formation of the trench 530, an insulating spacer deposition process may be performed. More particularly, with the fourth ion implantation mask 702 remaining in place, an insulating layer 704, such as an oxide (e.g., silicon dioxide), may be formed over the semiconductor structure, including on an upper surface of the fourth ion implantation mask 702 as well as on sidewalls and bottom surfaces of the trench 530. The insulating layer 704 may be formed, in one or more embodiments, using an oxide deposition or oxide growth process, or a combination of deposition and oxidation, although embodiments of the invention are not limited thereto. A blanket etch may be performed to selectively remove the insulating layer 704 on at least the bottom surface of the trench 530, thereby exposing the bottom surface of the trench 530 through the fourth ion implantation mask 702. The insulating material remaining on the sidewalls of the trench 530 may form trench sidewall spacers 704.

FIG. 7B depicts the formation of the shield implant layer 532. Specifically, the deep shielding region 532 may be formed proximate a bottom surface of the trench 530, for example by performing an ion implantation process (e.g., random or channeling ion implantation) or the like using a species of the second conductivity type (e.g., P-type, such as aluminum, boron or indium) using the fourth ion implantation mask 702 and the insulating layer 704 as an ion implantation mask to thereby form the deep shielding region 532 under the bottom surface of the trench 530. The trench sidewall spacers 704 are configured to protect the P-type species from being implanted into the active device layers (N+ layer 512, P-well 510 or the portion of the JFET layer 508 contacting the sidewalls of the trench 530) during the implant process. The deep shielding region 532 may be a shallow implant configured such that a bottom surface of the deep shielding region 532 extends vertically below a bottom surface of the JFET layer 508, although embodiments of the present invention are not limited thereto.

With reference to FIG. 7C, an additional JFET implant may be optionally formed in the vertical semiconductor structure. More particularly, using the fourth ion implantation mask 702 and the insulating layer 704 as an ion implantation mask, a species of the first conductivity type (e.g., N-type species, such as nitrogen, phosphorous, arsenic or antimony) may be implanted into the prescribed region of the drift region 502 exposed through the trench 530 to form a second JFET layer 706 in the drift region 502 under the deep shielding region 532. A depth of the second JFET layer 706 formed during this optional JFET implant process may be deeper than the implant process used to form the deep shielding region 532, so that the second JFET layer 706 is disposed beneath the deep shielding region 532 in the drift region 502. Since the same ion implantation mask 702 is used, the deep shielding region 532 and the second JFET layer 706 will be self-aligned with each other, and with the bottom of the trench 530, in the vertical direction. After forming the optional second JFET layer 706, the ion implantation mask 702 and the insulating layer 704 may be removed, such as by etching or another means, resulting in the vertical semiconductor structure shown in FIG. 7D.

FIG. 8 is a cross-sectional view depicting an enlarged portion of the illustrative vertical semiconductor device 800 shown in FIG. 7D, according to one or more embodiments of the present disclosure. With reference to FIG. 8, an insulating layer 802, such as an oxide (e.g., silicon dioxide), may be formed on sidewalls and a bottom of the trench 530 to conformally cover inner wall and bottom surfaces of the trench 530. An oxide growth or deposition process may be used to form the insulating layer 802.

The trench 530 may then be filled (e.g., using a deposition process) with polysilicon material (or another conductive or semiconductive material) to form a gate 804 of the vertical semiconductor device 800, the gate 804 being disposed on the insulating layer 802 in the trench 530; that is, the insulating layer 802 and the gate 804 may be sequentially stacked on the inner wall and bottom surfaces of the trench 530. In this manner, the insulating layer 802 may serve as a gate oxide layer of the vertical semiconductor device 800.

Like the illustrative vertical semiconductor device 600 shown in FIG. 6, the vertical semiconductor device 800 of FIG. 8 may be configured such that an edge of each of the JFET layer 508, P-well layer 510 and N+ layer 512 is vertically aligned (i.e., coplanar) with an edge of the P-type support shield 524 facing the trench 530. For embodiments in which the spacing S1 and/or S2 is independently controlled for a given one of the active device layers relative to the other active device layers, at least two of the implant layers are configured having an edge that is vertically aligned with the edge of the P-type support shield 524 facing the trench 530.

The support shields included in the power semiconductor devices according to embodiments of the present invention may extend further into the semiconductor layer structure than the trench shielding regions. With this design, displacement currents and avalanche currents that flow during an avalanche breakdown event will primarily pass from the drain to the source through the support shields rather than through the trench shielding regions and the sidewalls of the gate trenches. This design helps protect the gate oxide layers that line the gate trenches from higher electric fields that may be generated in response to displacement or avalanche currents, thereby improving the reliability of the power semiconductor devices according to embodiments of the present invention.

One potential reliability issue with conventional gate trench power semiconductor devices is that the JFET layer is formed as a continuous layer that extends underneath the gate trenches so that the JFET layer may extend underneath the trench shielding regions (depending upon the depth of the trench shielding regions), as shown in FIG. 3G. As discussed above, the JFET layer is more highly doped than the underlying drift region, and this higher doping density acts to increase the electric field values underneath the trench shielding region, putting increased stress on the gate dielectric layers lining the bottoms of the respective gate trenches.

As discussed above, using the fabrication methods disclosed herein, the JFET layer may be selectively implanted so that it is not a continuous layer and so that it does not extend underneath the gate trenches or only extends partially underneath the gate trenches, as shown in FIG. 5E. As a result, the region underneath the trench shielding regions is less highly doped n-type (for an n-type device), reducing the electric field values in the gate oxide layers during reverse blocking operation.

As discussed above, a series of ion implantation steps may be used to form the JFET layer, the well layer and the source layer of a power semiconductor device according to embodiments of the present invention. The JFET layer is the lowermost of these implanted layers, and hence requires the highest energy implant to form. The use of high energy ion implantation steps, however, has two potential disadvantages. First, when high energy implants are used, the dopant ions may physically damage the crystal lattice of the semiconductor layer structure, which may negatively impact the electrical performance thereof. Since the JFET layer is in the on-state operation current path, damage to the crystal lattice may negatively affect the performance of the device. Second, when an area of a semiconductor layer structure is doped using ion implantation, the dopant ions collide with atoms in the crystal lattice as they pass therethrough, and these collisions may redirect the dopant ions in different directions so that at least some of the dopant ions will move both vertically and laterally through the crystal lattice. The farther a dopant ion is implanted into a semiconductor layer structure, the more likely that the dopant ion includes some degree of lateral movement. This lateral movement results in the implanted region spreading out laterally with increased depth, which is often referred to as “blooming.” Thus, while the implanted regions are shown schematically in the figures using rectangular regions, in reality, some amount of blooming will typically occur, which results in the widths of the implanted regions increasing as the regions extend deeper into the semiconductor layer structure.

As discussed, for example, in U.S. Pat. No. 11,075,264, the entire content of which is incorporated herein by reference, a technique known as channeled ion implantation is known in the art in which the dopant ions are implanted at specific angles into the semiconductor layer structure so that the dopant ions are implanted along certain crystallographic axes in which channels are provided that allow the implanted dopant ions to have far fewer collisions with atoms in the crystal lattice. As a result, when channeled ion implantation is used, the dopant ions may be implanted to deeper depths in the semiconductor layer structure using lower implant energies, and the above-discussed blooming may be significantly reduced or even eliminated. In many cases, blooming is generally undesirable, as it results in the doping of regions that are not intended to be doped; that is, an expansion of the otherwise intended doped region. Thus, the use of channeled ion implantation techniques may allow for the formation of implanted regions having generally rectangular shapes and may allow for deeper implants using lower implant energies.

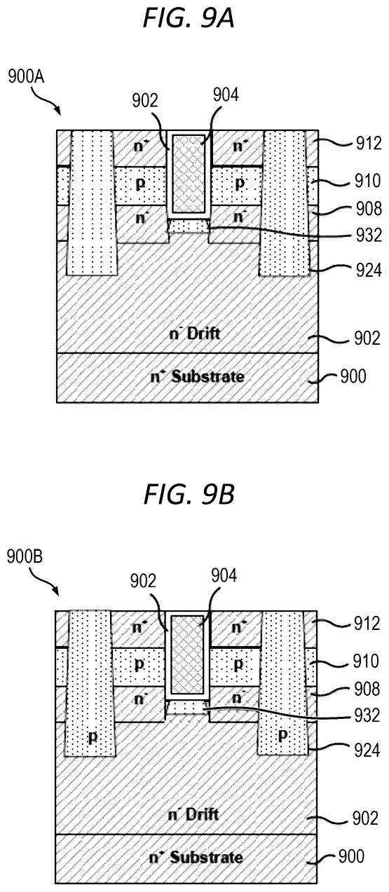

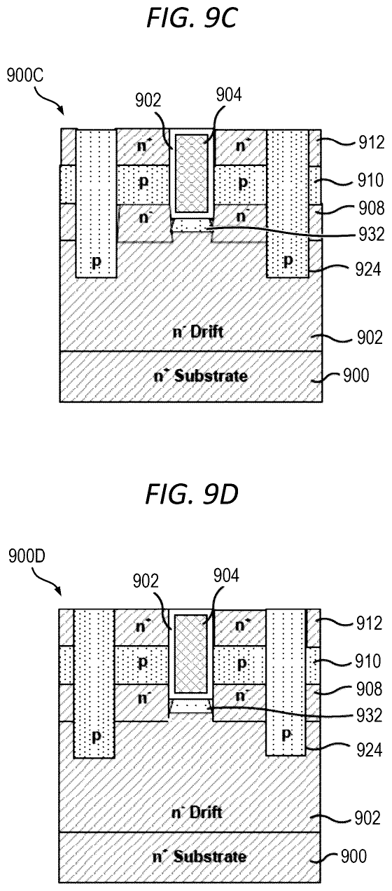

As discussed above, various of the ion implantation steps described above may be performed using either standard (i.e., non-channeled) or channeled ion implantation processes. For example, the ion implantation process used to form the JFET layer may be performed using either a standard ion implantation process or a channeled ion implantation process. Likewise, the ion implantation process used to form the support shields may also be performed using either a standard ion implantation process or a channeled ion implantation process. FIGS. 9A-9D schematically illustrate how the use of standard versus channeled ion implantation processes to form these layers/regions changes the structure of the completed device. In particular, FIG. 9A illustrates a power MOSFET 900A in which both the JFET layer 908 and the support shields 924 are formed using standard (non-channeled) ion implantation processes so that the implanted regions experience blooming. FIG. 9B illustrates a power MOSFET 900B in which the JFET layer 908 is formed using a channeled ion implantation process and the support shields 924 are formed using standard (non-channeled) ion implantation processes so that only the support shields 924 exhibit blooming. FIG. 9C illustrates a power MOSFET 900C in which the support shields 924 are formed using a channeled ion implantation process and the JFET layer 908 is formed using a standard (non-channeled) ion implantation process so that only the JFET layer 908 exhibit blooming. Finally, FIG. 9D illustrates a power MOSFET 900D in which both the JFET layer 908 and the support shields 924 are formed using channeled ion implantation processes so that these implanted regions do not experience blooming. In each of FIGS. 9A-9D the trench shielding region 932 is shown as being formed using a standard (non-channeled) ion implantation process, but it will be appreciated that embodiments of the present invention are not limited thereto.

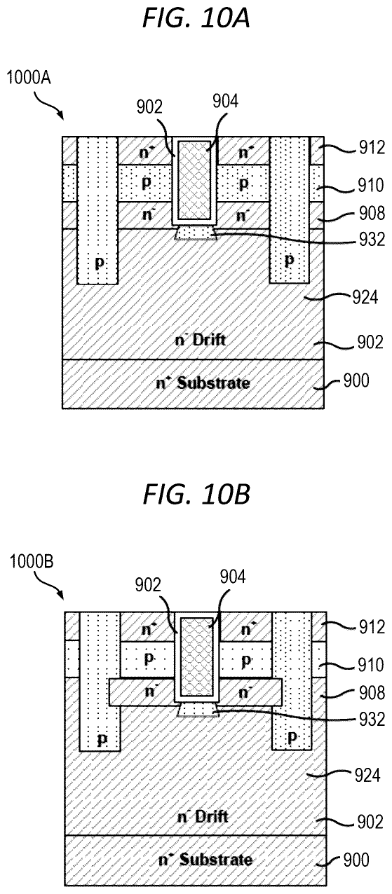

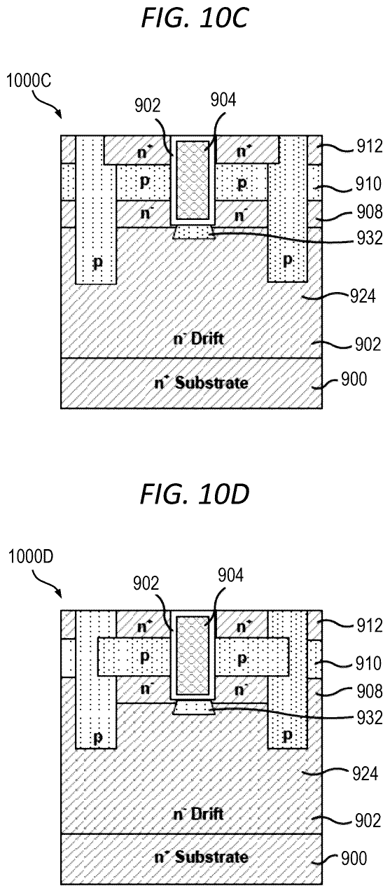

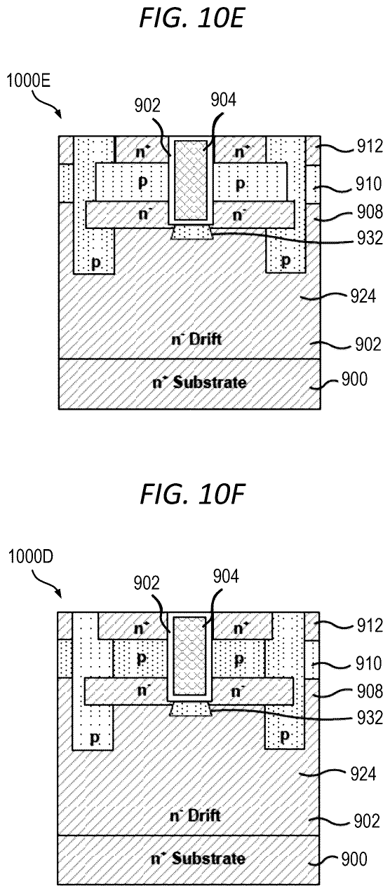

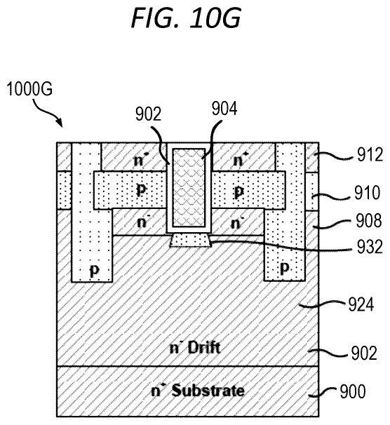

FIGS. 10A-10G are plan and cross-sectional views of power MOSFETs that can be fabricated using the above-described techniques. As shown in FIG. 10A, in some embodiments, a semiconductor layer structure is provided. A pair of support shields and a trenched gate structure are formed in the semiconductor layer structure, with the trenched gate structure in between the support shields. The support shields are spaced apart from one another in a first direction parallel to an upper surface of the semiconductor layer structure (i.e., in the horizontal direction in FIG. 9A), and the trenched gate structures has a longitudinal axis that extends in a second direction that is parallel to the upper surface of the semiconductor layer structure and perpendicular to the first direction (i.e., into the page in FIG. 9A). A JFET layer, a well layer and a source layer are formed in the semiconductor layer structure between the support shields. Outer edges of the JFET layer, the well layer and the source layer are aligned, in the second direction, with a sidewall that faces the trenched gate structure of a first of the support shields. Thus, in the embodiment of FIG. 10A, outer edges of all three of the JFET layer, the well layer and the source layer are aligned.

As shown in FIGS. 10B-10D, in other embodiments, outer edges of only two of the JFET layer, the well layer and the source layer may be aligned with a sidewall of a first of the support shields that faces the trenched gate structure. In FIG. 10B, outer edges of the JFET layer and the well layer are aligned with the sidewall of the first of the support shields that faces the trenched gate structure, while the outer edge of the JFET layer is not aligned with the sidewall of the first of the support shields that faces the trenched gate structure. In FIG. 10C, outer edges of the well layer and the JFET layer are aligned with the sidewall of the first of the support shields that faces the trenched gate structure, while the outer edge of the source layer is not aligned with the sidewall of the first of the support shields that faces the trenched gate structure. In FIG. 10D, outer edges of the JFET layer and the source layer are aligned with the sidewall of the first of the support shields that faces the trenched gate structure, while the outer edge of the well layer is not aligned with the sidewall of the first of the support shields that faces the trenched gate structure.

As shown in FIGS. 10E-10G, in other embodiments, outer edges of only one of the JFET layer, the well layer and the source layer may be aligned with a sidewall of a first of the support shields that faces the trenched gate structure. In FIG. 10E, the outer edge of the source layer is aligned with the sidewall of the first of the support shields that faces the trenched gate structure, while the outer edges of the well layer and the JFET layer are not aligned with the sidewall of the first of the support shields that faces the trenched gate structure. In FIG. 10F, the outer edge of the well layer is aligned with the sidewall of the first of the support shields that faces the trenched gate structure, while the outer edges of the source layer and the JFET layer are not aligned with the sidewall of the first of the support shields that faces the trenched gate structure. In FIG. 10G, the outer edge of the JFET layer is aligned with the sidewall of the first of the support shields that faces the trenched gate structure, while the outer edges of the source layer and the well layer are not aligned with the sidewall of the first of the support shields that faces the trenched gate structure.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A semiconductor device, comprising:
a semiconductor layer structure comprising a junction field-effect transistor (JFET) region of a first conductivity type, a well region of a second conductivity type on the JFET region, a source region of the first conductivity type on the well region and a plurality of support shields of the second conductivity type, the support shields being spaced apart from one another in a first direction parallel to an upper surface of the semiconductor layer structure and extending through the source region, the well region and the JFET region; and
a trenched gate structure formed in the semiconductor layer structure between a pair of adjacent support shields,
wherein edges of at least two of the JFET region, the well region and the source region are aligned in a second direction perpendicular to the first direction.

2. The semiconductor device according to claim 1, further comprising a trench shielding region of the second conductivity type formed in the semiconductor layer structure below the trenched gate structure.

3. The semiconductor device according to claim 1, wherein the first conductivity type is N-type and the second conductivity type is P-type.

4. The semiconductor device according to claim 1, wherein each of the JFET region, the well region and the source region is configured having an edge that is aligned, in the second direction, with the edge of the support shields facing the trenched gate structure.

5. The semiconductor device according to claim 1, wherein each of the JFET region, the well region and the source region is configured having an edge that is aligned, in the direction perpendicular to the upper surface of the semiconductor layer structure, with the edge of the support shields facing the trenched gate structure.

6. The semiconductor device according to claim 1, wherein the semiconductor layer structure comprises silicon carbide.

7. The semiconductor device according to claim 1, wherein the semiconductor layer structure further comprises a trench shielding region having the second conductivity type below the trenched gate structure.

8. The semiconductor device according to claim 7, wherein the JFET region extends in the second direction deeper into the semiconductor layer structure than the trench shielding region.

9. The semiconductor device according to claim 7, wherein the trench shielding region extends in the second direction deeper into the semiconductor layer structure than the JFET region.

10. The semiconductor device according to claim 7, wherein the semiconductor layer structure further comprises a second JFET region having the first conductivity type below the trench shielding region.

11. The semiconductor device according to claim 10, wherein the plurality of support shields extend in the second direction deeper into the semiconductor layer structure than the second JFET region.

12. The semiconductor device according to claim 1, wherein the plurality of support shields extend in the second direction deeper into the semiconductor layer structure than the JFET region.

13. The semiconductor device according to claim 1, wherein the trenched gate structure comprises:
an insulating layer on inner wall and bottom surfaces of the trenched gate structure; and
a gate on the insulating layer and at least partially filling the trenched gate structure.

14. A semiconductor device, comprising:
a semiconductor layer structure comprising a junction field-effect transistor (JFET) region of a first conductivity type, a well region of a second conductivity type on the JFET region, a source region of the first conductivity type on the well region; and
a trenched gate structure formed in the semiconductor layer structure between a pair of adjacent support shields, the trenched gate structure including a gate electrode,
wherein the JFET region does not extend completely underneath the trenched gate structure.

15. The semiconductor device according to claim 14, wherein the JFET region does not vertically overlap the gate electrode.

16. The semiconductor device according to claim 14, wherein the semiconductor layer structure further comprises a trench shielding region having the second conductivity type underneath the trenched gate structure.

17. (canceled)

18. (canceled)

19. The semiconductor device according to claim 16, wherein the semiconductor layer structure further comprises a second JFET region of the first conductivity type below the trench shielding region.

20. (canceled)

21. The semiconductor device according to claim 14, wherein the JFET region comprises a selectively implanted layer in the semiconductor layer structure.

22. (canceled)

23. A method of fabricating a semiconductor device, the method comprising:
forming a semiconductor layer structure comprising a junction field-effect transistor (JFET) region of a first conductivity type, a well region of a second conductivity type on at least a portion of the JFET region, a source region of the first conductivity type on at least a portion of the well region, and a plurality of support shields of the second conductivity type, the support shields being spaced apart from one another in a first direction parallel to an upper surface of the semiconductor layer structure and extending, in a second direction perpendicular to the first direction, through the source region, the well region and the JFET region; and
forming a trenched gate structure in the semiconductor layer structure between a pair of adjacent support shields,
wherein at least two of the JFET region, the well region and the source region are formed using a same ion implantation mask.

24. (canceled)

25. The method according to claim 23, further comprising forming a trench shielding region having the second conductivity type underneath the trenched gate structure.

26.-29. (canceled)

30. The method according to claim 25, wherein forming the trenched gate structure comprises:
providing a second ion implantation mask on an upper surface of the semiconductor layer structure, the second ion implantation mask defining a location of the trenched gate structure;
forming a trench extending in the second direction through the source region and the well region and partially into the JFET region;
forming a first insulating layer on sidewalls of the trench;
forming the trench shielding region by ion implantation through the trench using the second ion implantation mask;
forming a second insulating layer on sidewall and bottom surfaces of the trench; and
forming a gate on at least a portion of the second insulating layer.

31. The method according to claim 23, wherein forming the trenched gate structure comprises:
forming a trench extending in the second direction through the source region and the well region and partially into the JFET region;
forming an insulating layer on sidewall and bottom surfaces of the trench; and
forming a gate on at least a portion of the insulating layer.

32. (canceled)

33. A method of fabricating a semiconductor device, the method comprising:
forming a junction field-effect transistor (JFET) region of a first conductivity type;
forming a well region of a second conductivity type on at least a portion of the JFET region;
forming a source region of the first conductivity type on at least a portion of the well region; and
forming a trenched gate structure including a gate electrode, the trenched gate structure extending, in a first direction perpendicular to an upper surface of the semiconductor device, through the source region, the well region, and into at least a portion of the JFET region,
wherein at least two of the JFET region, the well region and the source region are formed using a same ion implantation mask.

34.-38. (canceled)
